(19) United States
(12) Patent Application Publication
(10) Pub. No.: US 2008/0203997 A1
(43) Pub. Date: Aug. 28, 2008

(54) DIGITAL CURRENT SENSE

(75) Inventors: Ryan Foran, Bullock, NC (US); Richard Kroeger, Apex, NC (US)

Correspondence Address: OSTROLENK FABER GERB & SOFFEN, 1180 AVENUE OF THE AMERICAS, NEW YORK, NY, 100368403, US

(73) Assignee: INTERNATIONAL RECTIFIER CORPORATION, El Segundo, CA (US)

(21) Appl. No.: 12/037,380

(22) Filed: Feb. 26, 2008

Related U.S. Application Data
(60) Provisional application No. 60/891,586, filed on Feb. 26, 2007.

(51) Int. Cl. G01R 19/00

(52) U.S. Cl. 324/76.11

(57) ABSTRACT

A circuit for measuring a current in an output inductor of at least one switching power supply having high- and low-side switches connected at a switching node, the output inductor having input and output terminals, the input terminal being connected to the switching node. The circuit including a sensing circuit for detecting a direction of current through the inductor, the sensing circuit generating a sense voltage related to the direction of current; a comparator circuit having an output terminal and input terminals coupled to the sensing circuit and receiving the sense voltage, the comparator circuit providing a comparison output of the sense voltage and an output voltage of the output inductor; and a switched current source circuit controlled by the comparison output for providing a reference current to the sensing circuit, the comparison output turning the switched current source circuit ON and OFF depending on the comparison output and having a duty cycle, whereby the average current flowing through the switched current source circuit is substantially equal to the average current in the sensing circuit and proportional to the duty cycle, the duty cycle being proportional to the inductor current.

### CROSS-REFERENCE TO RELATED APPLICATION

This application is based on and claims priority to U.S. Provisional Patent Application Ser. No. 60/891,586, filed on Feb. 26, 2007 and entitled DIGITAL CURRENT SENSE, the entire contents of which is hereby incorporated by reference.

### BACKGROUND OF THE INVENTION

The present invention relates to measuring the current through an inductor and more particularly to generating analog and digital measurements.

Digital Current Sense (DCS) is a method for measuring the current through an inductor. DCS derives a continuous steam of digital indicators, i.e., ones and zeros, in which the information about the current is embedded as the ratio of ones to zeros. A digital representation of an average current in the inductor can be achieved by simply counting the ones present within a specified averaging interval.

Several simple methods for generating an analog representation of the inductor current are known. The analog signal can be easily scaled to represent a power or current through an inductor.

Measuring the current in an inductor is a problem typically encountered in switching power supplies. Information about the inductor current may be used for a variety of functions including current limiting, load line regulation, current sharing, and power monitoring. These functions require accurate current monitoring with minimal added power dissipation. However, minimizing the power dissipation limits the available signal for current sensing.

Switching power supplies are popular in a variety of applications and are often chosen for their high efficiency, ability to create a wide variety of voltages, and compactness. As illustrated in FIG. 1, a variety of switching power supply topologies and architectures include the following common features: an output inductor L connected between a switching node of switches Q1 and Q2 and an output filter capacitor Cout. In all cases the voltage across the inductor L is switched between two nodes.

Equation 1 shows that in an ideal inductor the current changes in proportion to the voltage applied across it. However, as shown in Equation 1, the absolute current in an ideal inductor is independent of the voltage across it.

$$V = L * \frac{d i}{d t} \qquad Equation 1$$

To have knowledge of the absolute current in the inductor, a system must accurately integrate the voltage applied across the inductor and know the initial conditions or measure the absolute current in the inductor with a separate sense element. Resistor current sensing is one popular method of creating a voltage signal, which is proportional to the current flowing in the inductor. As illustrated in FIG. 2, and following Ohm's Law of Equation 2, a resistor placed in series with the inductor, generates a voltage across itself, which voltage is proportional to the current in the inductor. Since the voltage Vcs−Vout can be viewed as being proportional to the inductor current, the inductor current may be represented as in Equation 3.

$$\begin{matrix}Vcs - Vout = Iinductor * Rsense & Equation 2 \\ Iinductor = \frac{( Vcs - Vout )}{Rsense} & Equation 3\end{matrix}$$

Disadvantages of the above approach include additional power being dissipated in the resistive sense element thereby reducing the overall efficiency of the switching converter and a need for a precision power resistor.

Another popular method of creating a voltage signal which is proportional to the current flowing in an inductor is DCR current sensing illustrated in FIG. 3. DCR sensing commonly relies on the copper winding resistance of the inductor L, which has a significant temperature coefficient. An ideal inductor L would indicate that an average Vₚₕₐₛₑ voltage would be equal to Vₒᵤₜ. However, in realizable power supplies, there is a small, but measurable difference in the average Vₚₕₐₛₑ voltage and Vₒᵤₜ. This difference is due to the real intrinsic resistance of the inductor winding. This difference can be measured by filtering the Vₚₕₐₛₑ node and comparing it to Vₒᵤₜ.

The time constant chosen for the R_{CS}, C_{CS} filter matches the time constant of the inductor L and the intrinsic resistance, or DC resistance (DCR). This allows the V_{CS}−V_{OUT} signal to be correct even during transients, i.e., the changes in the switching duty cycle. Since an average voltage drop across the inductor L is proportional to the voltage drop across the parasitic winding resistance, DCR:

Average(Vphase)−Vout=Iinductor*DCR Equation 4

and Average(Vphase)=Vcs then Vcs−Vout=Iinductor*DCR. The voltage V_{CS}−V_{OUT} can be viewed as proportional to the inductor current Iinductor. Finally leading to Equation 5:

$$Iinductor = \frac{( Vcs - Vout )}{D C R} \qquad Equation 5$$

However, DCR current sensing also include disadvantages, such that the winding resistance DCR typically has a strong temperature dependence (Copper is ˜3900 ppm/degC.) and the DCR absolute value is typically not well known (5%).

Presently, analog amplifiers are used to sense the DCS signal, a separate sensor is required to sense the temperature. Further, an analog multiplier must be used to correct for temperature coefficient of inductor DCR. For digital output, an analog to digital converter is used to convert the sensed DCS signal, a separate sensor is required to sense the temperature and an analog to digital converter to convert the sensed temperature, and a digital multiplication to correct for temperature of inductor DCR. Also, to correct for temperature of inductor DCR an analog amplifier incorporates a resistor with appropriate temperature coefficient into gain network followed by analog to digital converter.

What is needed is a low power circuit (minimal circuitry) with inherent noise immunity for using the analog output to measure the inductor current and the power delivered by the inductor. The circuit should have analog and digital output capability, i.e., both analog and digital outputs are easily generated and the power is delivered by the inductor. The circuit should be configured to cancel temperature variation of the intrinsic parasitic resistance of a copper inductor without requiring an analog multiplier. The bandwidth and stability of the circuit should be well controlled by a clock frequency without requiring an analog loop. The output should be inherently accurate (achieved by minimizing and simplifying the analog components that contribute inaccuracies.

### SUMMARY OF THE INVENTION

It is an object of the present invention to provide a circuit for calculating the current through an inductor using DCR or resistor sensing, the circuit being configurable to cancel temperature variation of the intrinsic parasitic resistance of a copper inductor without requiring an analog multiplier.

It is another object of the present invention to provide a circuit for counting logical ones of the calculated current over a period of time to produce a digital word representing the average current flowing in the inductor over the specified period of time.

It is yet another object of the present invention to provide a circuit that can filter the calculated current with a simple filter to produce an analog voltage proportional to the current flowing in the inductor or the power delivered through the inductor.

A circuit for measuring a current in an output inductor of at least one switching power supply is provided. The circuit having high- and low-side switches connected at a switching node, the output inductor having input and output terminals, the input terminal being connected to the switching node. The circuit including a sensing circuit for detecting a direction of current through the inductor, the sensing circuit generating a sense voltage related to the direction of current; a comparator circuit having an output terminal and input terminals coupled to the sensing circuit and receiving the sense voltage, the comparator circuit providing a comparison output of the sense voltage and an output voltage of the output inductor; and a switched current source circuit controlled by the comparison output for providing a reference current to the sensing circuit, the comparison output turning the switched current source circuit ON and OFF depending on the comparison output and having a duty cycle, whereby the average current flowing through the switched current source circuit is substantially equal to the average current in the sensing circuit and proportional to the duty cycle, the duty cycle being proportional to the inductor current.

Other features and advantages of the present invention will become apparent from the following description of the invention that refers to the accompanying drawings.

### BRIEF DESCRIPTION OF THE DRAWINGS

FIG. 1 is a circuit diagram of a commonly known buck switching power supply;

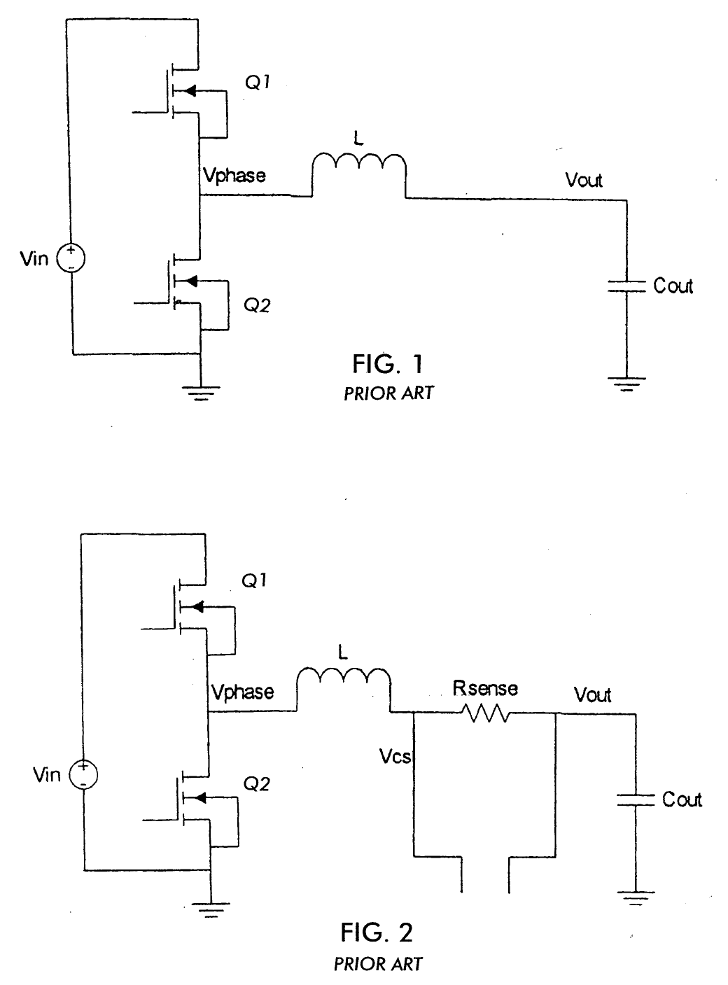

FIG. 2 is a circuit diagram of a commonly known switching power supply providing resistor sensing;

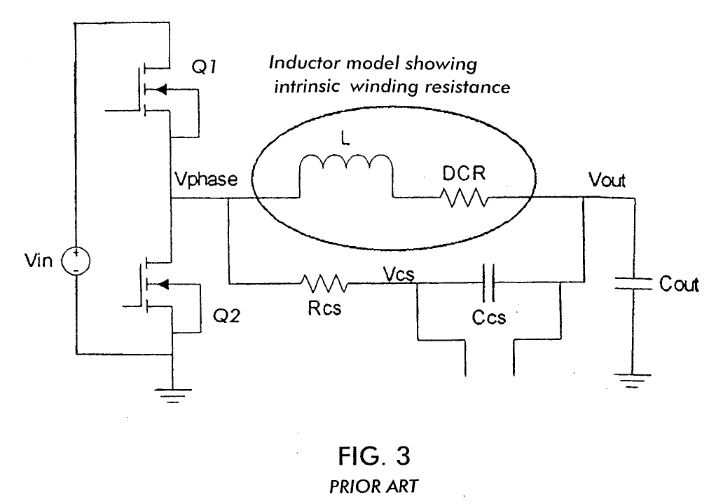

FIG. 3 is a circuit diagram of a commonly known switching power supply providing DCR current sensing;

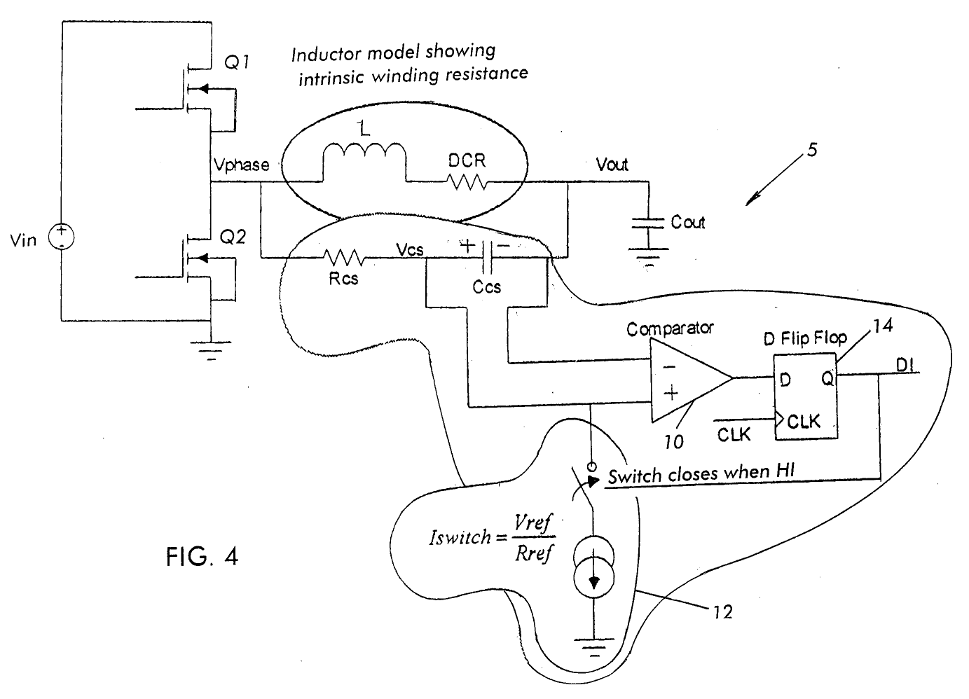

FIG. 4 is a circuit diagram of a switching power supply of the present invention configured for positive inductor current;

FIG. 5 is a circuit diagram of a switching power supply of the present invention configured for positive and negative inductor current;

FIG. 6 is a circuit diagram of the present invention configured to measure inductor current in a plurality of switching power supplies;

FIG. 7 is diagram of a circuit for converting comparison output to an analog voltage proportional to the inductor current, the lower portion of this Figure is a graph showing output voltage of the circuit when the input is at 25%, 50%, and 75% of the duty cycle;

FIG. 8 is a circuit diagram of the present invention configured to use a resistor to sense current in the inductor;

FIG. 9 is a circuit diagram of a counter to convert the output of a comparator of the present invention to average current over time;

FIG. 10 is a diagram of an alternative circuit to that of FIG. 7 for converting comparison output to an analog voltage by creating analog current/voltage proportional to the inductor current; and

FIG. 11 is a circuit diagram of the present invention configured to match DCS filter time constant to DCR time constant.

### DETAILED DESCRIPTION OF EMBODIMENTS OF THE INVENTION

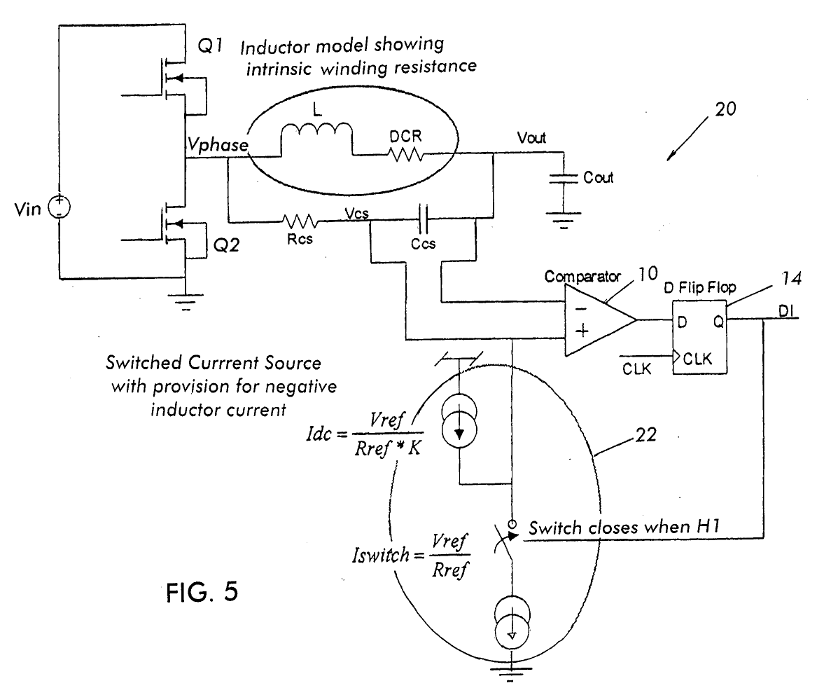

One embodiment of the present invention is illustrated in FIG. 4, where a DCS circuit 5 is shown. To assure correct operation of this embodiment positive inductor current must be maintained. The circuit 5 includes a comparator 10, and a switched current source Iswitched 12, and a filter comprising a resistor R_{CS} and a capacitor C_{CS}. The switched current source 12 can be any circuit which sinks an average output current that increases with the increasing duty cycle D, and can supply a sufficient amount of an average current to cancel the average current flowing through the resistor R_{CS}. The comparator 10 can be clocked by a D Flip-Flop 14 placed in series with or asynchronous to the output of the comparator 10. Using a clocked comparator 10 has the advantage that the switching frequency of the DCS circuit 5 can be controlled without hysteresis or knowledge of the frequency components of the inductor current Iinductor. The circuit 5 forms a portion of a delta-sigma analog to digital converter (ADC) and shares the filter with the DCR.

The value of the switched current can easily be made to be dependent on a resistor, which is chosen to have a temperature coefficient which matches the temperature coefficient of the intrinsic inductor winding resistance DCR. This will facilitate a measurement of the inductor current Iinductor, which is independent of the temperature.

The output of the DCS circuit 5 is a signal DI, which is a continuous stream of ones and zeros in which the ratio of ones to zero contains the information about the inductor current Iinductor. A digital representation of an average inductor current can be achieved by simply counting the ones present in the output signal DI over a specified averaging interval. An analog representation of the output signal DI can be achieved by applying the RC filter R_{CS} C_{CS} to the output signal DI to find an average value. This analog signal can easily be scaled to represent the power delivered through the inductor L.

The circuit 5 contains a high gain negative feedback loop made-up of the comparator 10, D Flip-Flop 14, and switched current source 12. In the feedback loop, the inputs of the comparator 10 are driven to be substantially equal. For positive inductor currents, the DCS circuit 5 regulates the average voltage across the capacitor C_{CS} to near zero in the following way:
when voltage V_{CS} on the capacitor C_{CS} is greater than the output voltage Vₒᵤₜ, the digital output of the comparator 10 goes high, thereby causing an increase in the current removed from the capacitor C_{CS} by the switched current source 12, and a net negative current into the capacitor C_{CS};
when voltage V_{CS} on the capacitor C_{CS} is less than the output voltage Vₒᵤₜ, the digital output of the comparator goes low, thereby causing a decrease in the current removed from the capacitor C_{CS} by the switched current source 12 and a net positive current into the capacitor C_{CS}. In this way, the output of the comparator 10 is continuously changing between high and low to keep the average current flowing through the switched current source 10 equal to the average current flowing through the resistor R_{CS}. The output of the DCS circuit 5 or the duty cycle DI is proportional to the average current through the switched current source 10.

The current through the resistor R_{CS} is proportional to the inductor current, the average current through the resistor R_{CS} is substantially equal to the average current through the switched current source 10, and the average current through the switched current source 10 is proportional to the Duty Cycle DI. Therefore, the Duty Cycle DI is proportional to the inductor current.

The transfer function of the switched current source 10 is flexible and can be controlled by a variety of relatively simple analog circuits, the relationship between the inductor current and the duty cycle DI is flexible and can be scaled and referenced to a variety of useful voltages and resistors.

Once information about the inductor current is captured in the duty cycle DI by the DCS circuit 5, it can be used in a variety of ways to scale, invert, gain, sum, offset, and multiply by other voltage(s) and resistor(s).

Furthermore, because of the digital nature of the duty cycle DI, it can easily be converted to a digital word, which is proportional to the inductor current by means of a simple counter.

It is an inherent advantage that once the inductor current information is embedded in the duty cycle DI; it is relatively noise immune since the output signal DI is a digital signal. It can be transported and manipulated by the system in simple, low power, and easily implemented circuits due to the duty cycle's digital nature.

The system can be configured so that the time constant R_{CS}*C_{CS} is long compared to the sampling clock CLK. Since the feedback loop holds the inputs of the comparator 10 to be substantially equal, simple algebra can be used to analyze the steady state, i.e., average over many clock cycles, operation of the DCS system.

The current flowing through the resistor R_{CS} is equal to the average current flowing through the switched current source 10. Summing currents at the V_{CS} node, with the knowledge that Vcs=Vout because of the feedback loop,

$$\frac{Average ( Vphase ) - Vout}{Rcs} = Iswitched * DI \qquad Equation 6$$

Substituting Equation 4 into Equation 6,

$$\frac{Iinductor * D C R}{Rcs} = Iswitched * DI \qquad Equation 7$$

Since the current Iswitched is defined as Vref/Rref,

$$\frac{Iinductor * D C R}{Rcs} = \frac{Vref}{Rref} * DI \qquad Equation 8$$

and solving for DI,

$$DI = Iinductor * DCR * ( \frac{Rref}{Rcs} ) * ( \frac{1}{Vref} ) \qquad Equation 9$$

This notable result shows that DI is only a function of the inductor current and constants. It also makes it obvious that if Rref has the inverse temperature coefficient of the DCR then, the answer becomes temperature independent. Solving for the current through the inductor Iinductor,

$$Iinductor = DI * ( \frac{Vref}{DCR} ) * ( \frac{Rcs}{Rref} ) \qquad Equation 10$$

The above described invention is compatible with resistor current sensing and DCR current sensing methods. Because the resistor Rref can be made having any desired temperature coefficient, the present invention facilitates correcting for the temperature coefficient of the winding resistance in DCR current sensing applications or any other desired temperature coefficient, including zero temperature coefficient with resistor current sensing.

Similar functionality may be attained to facilitate measuring negative inductor current by changing the switched current source polarity and inverting the output signal DI going into the switch. Facilitating both positive and negative inductor current can be accommodated in at least the following ways:
1. A switched current source and a DC current source of opposite polarity summing in the V_{CS} node.
2. Two switched current sources of opposite polarity summing into the V_{CS} node (the switches must be out of phase and of the proper polarity to force negative feedback)

For a DC input, the system will naturally reach a steady state operation in which the pattern of ones and zeros repeats as often as possible, i.e., highest pattern frequency. As an example, the system would naturally output 01010101 instead of 00110011, although both possess the same ratio of ones to zeros.

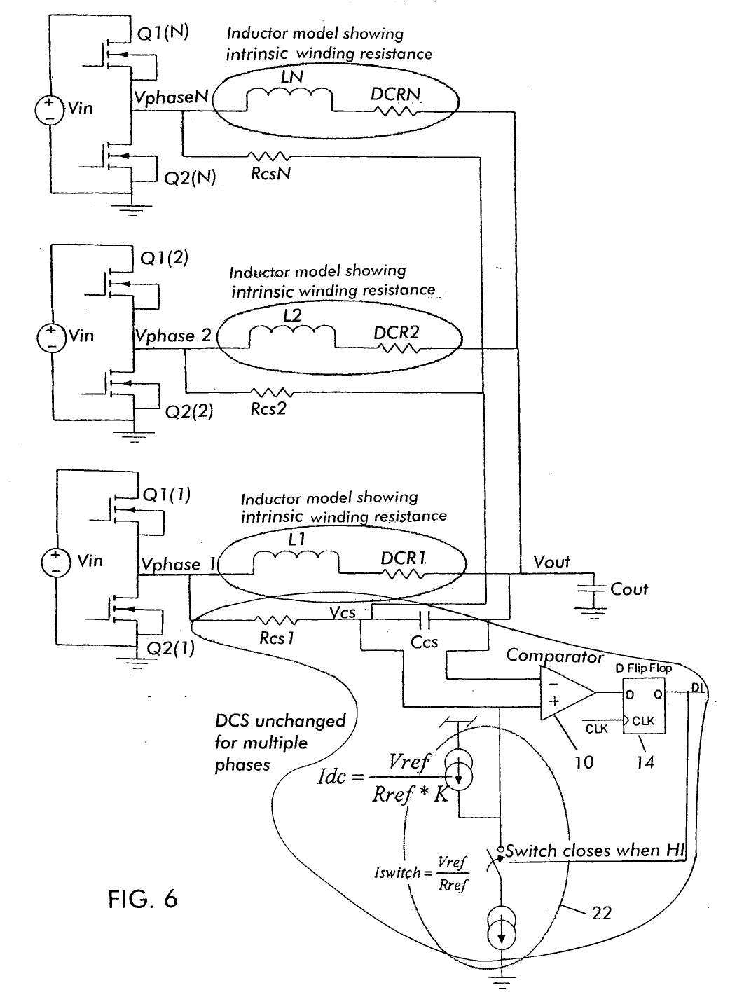

Another embodiment of the present invention illustrated in FIG. 5, includes the same DCS concept with a switched current source 22 configured to also facilitate negative inductor currents.

Since the feedback loop, including the comparator 10, the D Flip-Flop 14 and the switched current source 22, holds the inputs of the comparator 10 to be substantially equal, simple algebra can be used to analyze the steady state operation, i.e., average over many clock cycles, of the DCS system that assumes Vcs=Vout.
Summing the currents at the V_{CS} node, the current flowing through R_{CS} equals average current flowing through the switched current source 22, with knowledge that because of the feedback loop Vcs=Vout and resulting in Equation 11.

$$\frac{Average ( Vphase ) - Vout}{Rcs} + Idc = Iswitched * DI \qquad Equation 11$$

Substituting Equation 4 into Equation 11 results in

$$\frac{Iinductor * DCR}{Rcs} + Idc = Iswitched * DI \qquad Equation 12$$

Since, as shown in FIG. 5, Iswitched is defined as Vref/Rref, and Idc is defined as Vref/(Rref*K),

$$\frac{Iinductor * DCR}{Rcs} + ( \frac{Vref}{Rref * K} ) = \frac{Vref}{Rref} * D 1 \qquad Equation 13$$

### Solving for DI,

$$DI = Iinductor * DCR * ( \frac{Rref}{Rcs} ) * ( \frac{1}{Vref} ) + \frac{1}{K} \qquad Equation 14$$

This notable result shows that DI is only a function of the inductor current and constants. The results also clarify that if Rref has the opposite temperature coefficient of DCR, then the result becomes temperature independent. It is also notable that DI's duty ratio includes an “offset” of 1/K. In other words, at zero inductor current, DI will still give a positive duty ratio of 1/K. For example, if K is 2, then at zero current, the DI's duty ratio would be 50% (50% ones). Solving for Iinductor,

$$Iinductor = ( DI - \frac{1}{K} ) * ( \frac{Vref}{DCR} ) * ( \frac{Rcs}{Rref} ) \qquad Equation 15$$

Similar functionality could be attained by switching the location of the DC and switched current sources (with an inverter required between the output of the DFF and the switched current source).

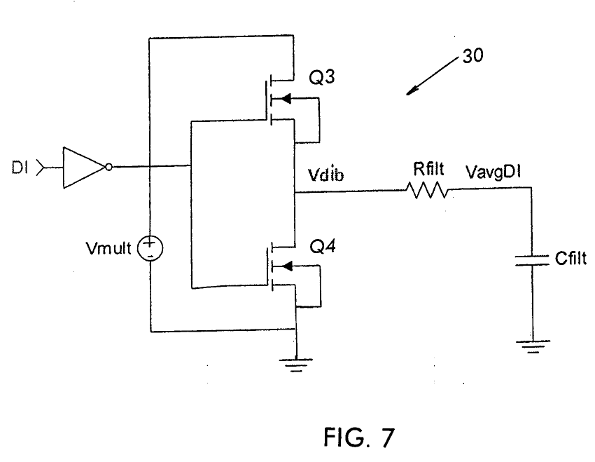

Another embodiment of the present invention illustrated in FIG. 6, includes only one extra resistor R_{CS}N per phase to measure the total current in multiple inductors. Using the same analysis techniques as above, it can be easily shown that:

$$DI = ( \frac{Iinductor 1 * DCR 1}{Rcs 1} + \frac{Iinductor 2 * DCR 2}{Rcs 2} + \frac{Iinductor N * DCR N}{Rcs N} ) * ( Rref ) * ( \frac{1}{Vref} ) + \frac{1}{K} \qquad Equation 16$$

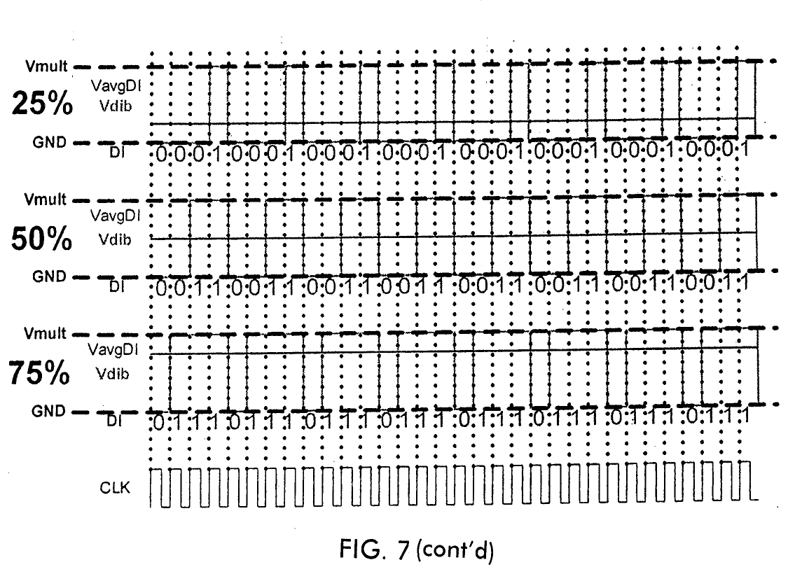

The DI output can be easily converted to an analog voltage proportional to the inductor current. A circuit 30, illustrated in FIG. 7, provides DI as input to a switching stage having high- and low-side switches Q3 and Q4 connected at a node to provide a voltage Vdib. An output filter including series connected resistor Rfilt and capacitor Cfilt is connected between the node and the ground. The graph portion of FIG. 7 shows the DI output voltage of the circuit VavgDI when DI is at 25%, 50%, and 75% of the duty cycle. The average value of the voltage Vdib is calculated using the output filter Rfilt*Cfilt, as

VavgDI=average(Vdib) Equation 17

Because Vdib is simply Vmult modulated by DI,

Vdib=Vmult*DI Equation 18

Since it was shown that DCS can produce DI, which is proportional to inductor current,

DI=scalar*Iinductor Equation 19

Substituting Equation 19 into Equation 18,

Vdib=Vmult*scalar*Iinductor Equation 20

Applying the averaging function to both sides of the equation,

average(Vdib)=average(Vmult*scalar*Iinductor) Equation 21

Substituting Equation 17 into Equation 21 results in

VavgDI=average(Vmult*scalar*Iinductor) Equation 22

Rearranging shows that the output is dependent only on the average current in the inductor, a constant scalar, and Vmult. If Vmult is chosen to be a constant also, then VavgDI becomes a scaled representation of the inductor current, Iinductor.

VavgDI=average(Iinductor)*Vmult*scalar Equation 23

If Vmult is chosen to be the output voltage of the buck converter, then VavgDI becomes a scaled representation of the power being delivered through the inductor. Choosing Vmult=Vout and substituting that equation into Equation 23,

VavgDI=average(Iinductor)*Vout*scalar Equation 24

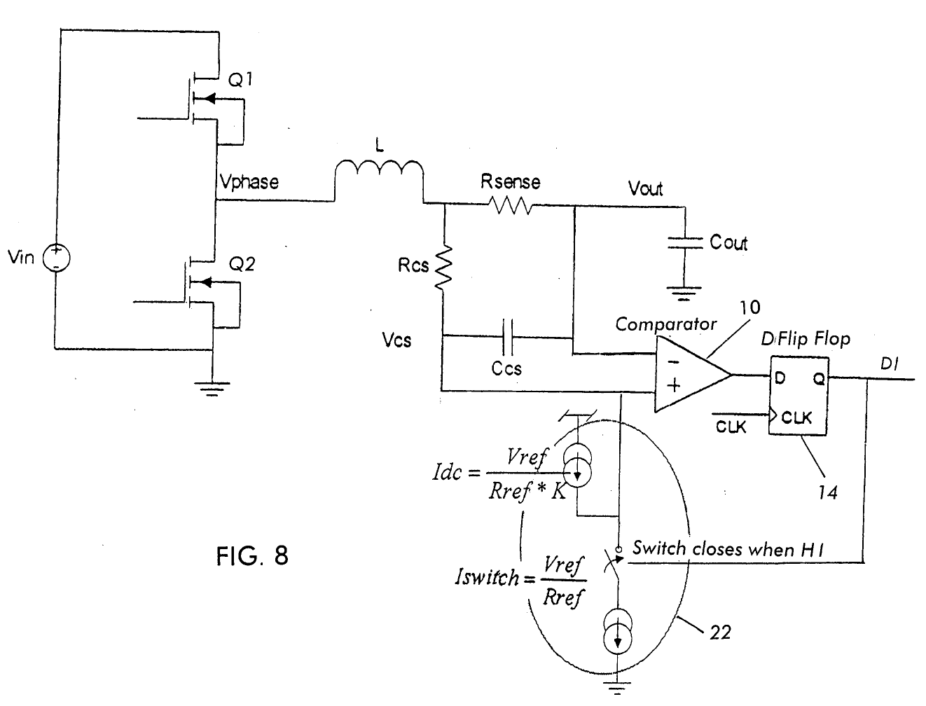

In an embodiment illustrated in FIG. 8, the same DCS configurations can be used to sense the signal generated from a resistor Rsense (as opposed to a DCR current sense signal). It can be assumed that Rsense<<R_{CS}. Using the same analysis techniques, it can easily be shown that:

$$DI = Iinductor * Rsense * ( \frac{Rref}{Rcs} ) * ( \frac{1}{Vref} ) + \frac{1}{K} \qquad Equation 25$$

### Solving for Iinductor,

$$Iinductor = ( DI - \frac{1}{K} ) * ( \frac{Vref}{Rsense} ) * ( \frac{Rcs}{Rref} ) \qquad Equation 26$$

It is worth noting that this is essentially the same format as that which results from DCS when the circuit is configured for DCR sensing. Therefore, the same circuit may be designed for an IC and the choice of sense elements can be left to the user.

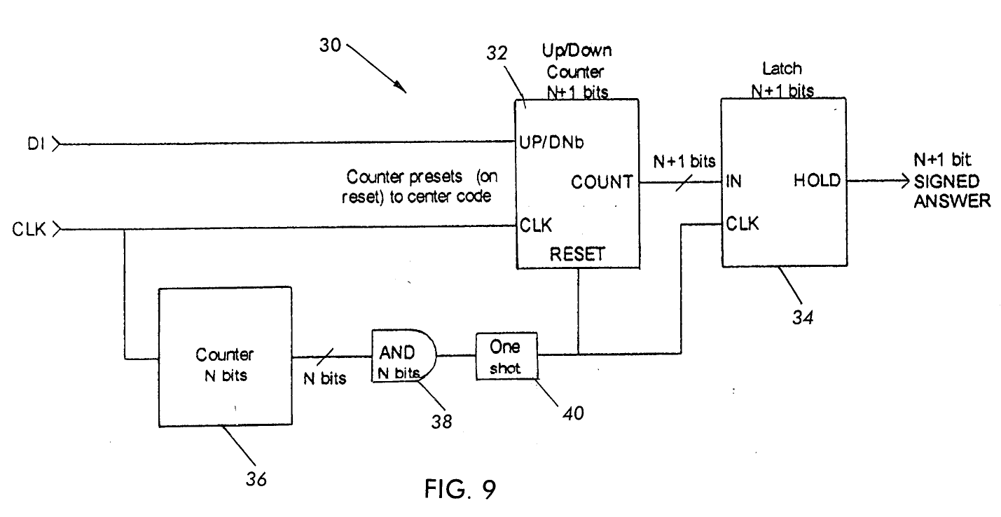

FIG. 9 illustrates a circuit to average the inductor current using the digital output DI. The circuit 30 is tailored for DCS for positive and negative currents with a K value of 2. The circuit 30 includes an up/down counter circuit 32 for receiving the N+1 bits of the digital output DI of the comparator 10 (FIG. 8) and a clock signal CLK. The counted bits are passed to a latch circuit 34. The circuit 30 further includes series connected N-bit counter circuit 36, N-bit AND circuit 38, and a one-shot circuit 40 that provides a reset signal to the up/down counter circuit 32 and a clock signal to the latch circuit 34.

The clock signal CLK provided to the up/down counter circuit 32 is the same clock signal that is used to clock the D Flip Flop 14 (FIG. 8) of DCS. This way the digital output DI signal is synchronous with the clock signal CLK. The averaging interval will be (1/CLK)*2̂n.

The offset K having the value of 2 means that there will be a 50% DI offset, which means that zero inductor current results in a 50% ratio of ones to zero in the digital output DI. For negative inductor currents, the DI ratio will be less than 50%, i.e., fewer ones than zeros, and for positive inductor currents, the DI ratio will be greater than 50%, i.e., more ones than zeros.

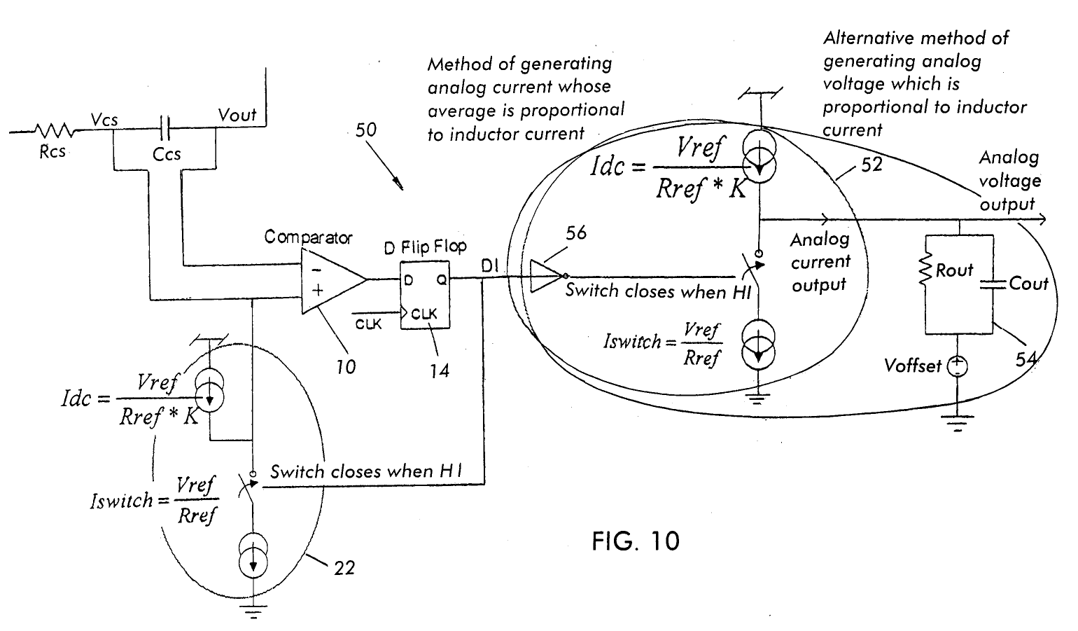

FIG. 10 illustrates an alternative method of generating analog output voltage DI proportional to the inductor current. This embodiment may be particularly useful for generating voltages which are not relative to ground, e.g., Voffset, which could also be chosen to be zero. In addition to the comparator circuit 10, the D Flip-Flop 14 and the switched current source 22, the circuit 50 includes an inverter 56 and a switched current source 52, having current sources Idc and Iswitch that are identical to these of the switched current source 22. The inverse of the compared output DI being used to control the current source Iswitch of the switched current source 52. The current and voltage provided by the switched current source 52 passing through the circuit 54 that includes parallel coupled resistor Rout and capacitor Cout. One terminal of the parallel coupled resistor and capacitor being connected to the switched current source 52 and the other terminal being connected to a voltage source Voffset.

Applications based on this embodiment may include:
1. “DROOP” signal in switching converter feedback loop. This is a typical situation where the regulated output voltage of the converter is chosen to be dependent on load current—emulating a resistor in series with the output of the converter.
2. Current limiting function in a switching converter.
3. Stability enhancements to a switching converter which require real-time knowledge of inductor current (current mode control).

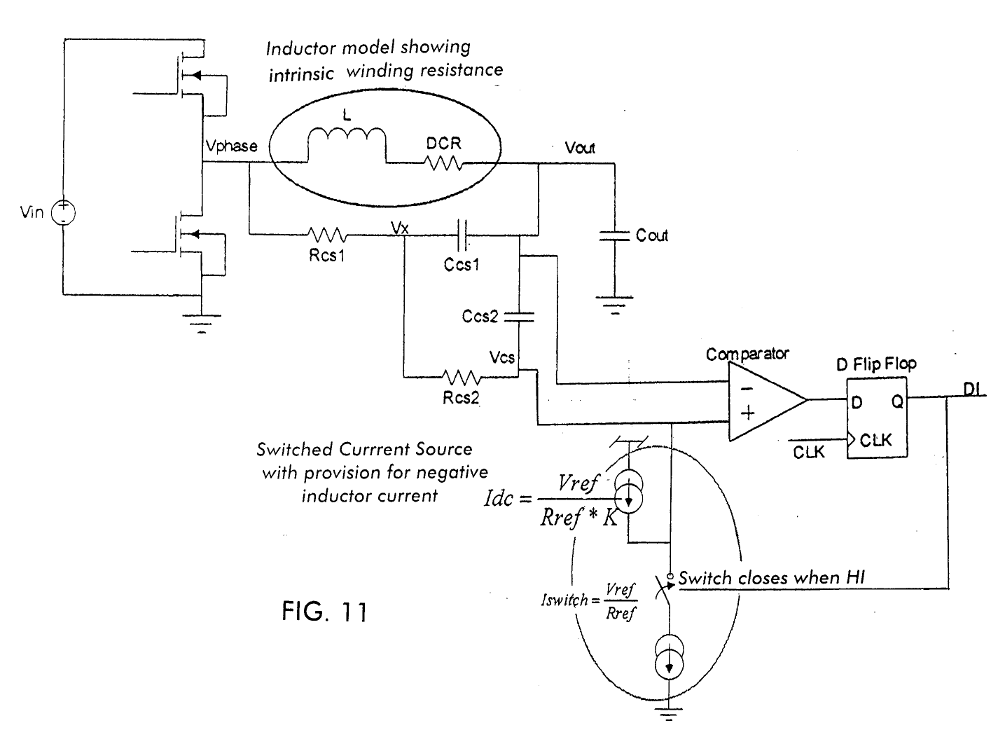

In another embodiment, illustrated in FIG. 11, the DCS filter time constant is made to match the DCR filter time constant with the addition of a second RC, R_{CS2} and C_{CS2} to the loop filter. The current in the inductor (with respect to Vout):

Average(Vphase)=Iinductor*(s*L+DCR) Equation 27

Using voltage division to find Vx:

$$Vx = Average ( Vphase ) * \frac{\frac{R 2}{1 + s * R 2 * Ccs 1}}{R 1 + ( \frac{R 2}{1 + s * R 2 * Ccs 1} )} \qquad Equation 29$$

Expanding on impedances in parallel:

$$Vx = Average ( Vphase ) * \frac{Rcs 2 \vert \vert ( 1 / s * Ccs 1 )}{Rcs 1 + ( Rcs 2 \vert \vert ( 1 / s * Ccs 1 ) )} \qquad Equation 28$$

Multiplying numerator and denominator by (1/(1+s*Rcs2*Ccs1)):

$$\begin{matrix}Vx = Average ( Vphase ) * \frac{Rcs 2}{Rcs 1 + ( s * Rcs 1 * Rcs 2 * Ccs 1 ) + Rcs 2} \\ Redistributing \text{:} & Equation 30 \\ Vx = Average ( Vphase ) * \frac{Rcs 2}{( Rcs 1 + Rcs 2 ) * ( 1 + s * \frac{Rcs 1 * Rcs 2}{Rcs 1 + Rcs 2} )} & Equation 31\end{matrix}$$

### Substituting Equation 29:

$$Vx = Iinductor * ( s * L + DCR ) * \frac{Rcs 2}{( Rcs 1 + Rcs 2 ) * ( 1 + s * \frac{Rcs 1 * Rcs 2}{Rcs 1 + Rcs 2} * Ccs 1 )} \qquad Equation 32$$

Choosing Rcs1, Rcs2, and Ccs1 such that:

$$\frac{Rcs 1 * Rcs 2}{Rcs 1 + Rcs 2} * Ccs 1 = \frac{L}{DCR} \qquad Equation 33$$

Substituting Equation 33 into Equation 32:

$$\begin{matrix}Vx = Iinductor * ( s * L + D C R ) * \frac{Rcs 2}{\begin{matrix}( Rcs 1 + Rcs 2 ) * \\ ( 1 + s * \frac{L}{D C R} )\end{matrix}} & Equation 34 \\ Rearranging \text{:} \\ Vx = \begin{matrix}Iinductor * ( s * L + D C R ) * \\ [ \frac{1}{( 1 + s * \frac{L}{D C R} )} ] * ( \frac{Rcs 2}{Rcs 1 + Rcs 2} )\end{matrix} & Equation 35\end{matrix}$$

Multiplying the middle term (the one in square brackets) by DCR:

$$Vx = \begin{matrix}Iinductor * ( s * L + D C R ) * \\ [ \frac{D C R}{( D C R + s * L )} ] * ( \frac{Rcs 2}{Rcs 1 + Rcs 2} )\end{matrix} \qquad Equation 36$$

Canceling terms:

$$Vx = Iinductor * D C R * ( \frac{Rcs 2}{Rcs 1 + Rcs 2} ) \qquad Equation 37$$

### Applying Ohms Law to Rcs2:

$$Ircs 2 = \frac{Vx}{Rcs 2} \qquad Equation 38$$

Substituting Equation 37 into Equation 38:

$$Ircs 2 = \frac{Iinductor * DCR * ( \frac{Rcs 2}{Rcs 1 + Rcs 2} )}{Rcs 2} \qquad Equation 39$$

### Canceling Rcs2's:

$$Ircs 2 = \frac{Iinductor * DCR}{Rcs 1 + Rcs 2} \qquad Equation 40$$

Summing currents at the Vcs:

Ircs2=Idc+Iswtiched*DI Equation 41

Substituting Equation 40 into Equation 41:

$$\frac{Iinductor * D C R}{Rcs 1 + Rcs 2} + Idc = Iswitched * DI \qquad Equation 42$$

### Solving for DI:

$$\frac{Iinductor * D C R}{Rcs 1 + Rcs 2} + Idc = Iswitched * DI \qquad Equation 43$$

Since Iswitched is defined as Vref/Rref, and Idc is defined as Vref/(Rref*K),

$$\frac{Iinductor * D C R}{Rcs 1 + Rcs 2} + ( \frac{Vref}{Rref * K} ) = \frac{Vref}{Rref} * DI \qquad Equation 44$$

### Solving for DI,

$$DI = Iinductor * D C R * ( \frac{Rref}{Rcs 1 + Rcs 2} ) * ( \frac{1}{Vref} ) + \frac{1}{K} \qquad Equation 45$$

This result shows that DI is identical to Equation 14 except that the gain depends on the sum of the two resistors instead of the single. This result is valid for transients as well as DC operation. Solving for Iinductor,

$$Iinductor = ( DI - \frac{1}{K} ) * ( \frac{Vref}{D C R} ) * ( \frac{Rcs 1 + Rcs 2}{Rref} ) \qquad Equation 46$$

Equation 46 is similar to Equation 15 except the gain term is dependent on the sum of the current sense resistors instead of the single resistor.

Although the present invention has been described in relation to particular embodiments thereof, many other variations and modifications and other uses will become apparent to those skilled in the art. It is preferred, therefore, that the present invention not be limited by the specific disclosure herein.

What is claimed is:

1. A circuit for measuring a current in an output inductor of at least one switching power supply having high- and low-side switches connected at a switching node, the output inductor having input and output terminals, the input terminal being connected to the switching node, the circuit comprising:
a sensing circuit for detecting a current through the inductor and generating a sense voltage related to the current through the inductor;
a circuit for generating from the sense voltage a pulse width modulated signal having a duty cycle; and
a feedback circuit responsive to the pulse width modulated signal for driving the sense voltage to zero whereby the pulse width modulated signal duty cycle is proportional to the average inductor current.

2. The circuit of claim 1, wherein
the sensing circuit detects a direction of current through the inductor, the sense voltage being related to the direction of the current through the inductor;
the circuit for generating a pulse width modulated signal comprises a comparator circuit having an output terminal and input terminals coupled to said sensing circuit and receiving said sense voltage, the comparator circuit providing said pulse width modulated signal, said pulse width modulated signal comprising a comparison output between said sense voltage and an output voltage at the output terminal of said output inductor;
said feedback circuit comprises a switched current source circuit controlled by said comparison output for providing a reference current to the sensing circuit, the comparison output turning the switched current source circuit ON and OFF depending on said comparison output,
whereby the average current flowing through the switched current source circuit is substantially equal to the average current in the sensing circuit and proportional to said duty cycle, the duty cycle being proportional to the inductor current.

3. The circuit of claim 2, wherein the comparison output is a continuous stream of ones and zeros, the ratio of ones to zeros in said continuous stream being proportional to the average current in the output inductor.

4. The circuit of claim 3, further comprising a synchronizing circuit connected to the comparator circuit for synchronizing the comparison output to a clock signal.

5. The circuit of claim 4, wherein the synchronizing circuit comprises a flip-flop circuit receiving said comparison output and said clock signal.

6. The circuit of claim 3, wherein a digital representation of the average current in the output inductor is achieved by counting the ones present in the comparison output over a specified averaging interval.

7. The circuit of claim 2, wherein the switched current source circuit is turned ON and OFF by a feedback loop that includes the switched current source circuit and the comparator circuit, the feedback loop driving the inputs of the comparator circuit to be substantially equal.

8. The circuit of claim 2, wherein
if the current through the inductor is determined to flow in a positive direction toward the output terminal, the digital output of the comparator circuit goes high causing an increase in the current away from the sensing circuit toward the switched current source circuit and
if the current through the inductor is determined to flow in a negative direction away from the output terminal, the digital output of the comparator circuit goes low causing a decrease in the current away from the sensing circuit toward the switched current source circuit.

9. The circuit of claim 8, wherein if the current through the inductor is determined to flow in the positive direction, the switched current source circuit sinks an average current that increases as the duty cycle increases and supplies a sufficient amount of the average current to cancel the average current in the sensing circuit, and
if the current through the inductor is determined to flow in the negative direction, a polarity of the switched current source circuit is changed and the current flows from the switched current source circuit to the sensing circuit.

10. The circuit of claim 2, wherein the switched current source circuit comprises at least one current source that is defined as Iswitch=Vref/Rref, where Vref is a reference voltage, Rref is a reference resistance, a resistance of the sensing circuit is defined as R_{CS}, and the comparison output is defined as DI, then the current in the output inductor can be defined as
$$Iinductor = DI * ( \frac{Vref}{D C R} ) * ( \frac{Rcs}{Rref} ) .$$

11. The circuit of claim 9, wherein the switched current source circuit comprises at least two current sources including one sinking current directed away from the sensing circuit for positive inductor current and one sourcing current directed to the sensing circuit for negative inductor current.

12. The circuit of claim 11, wherein the at least two current sources are defined as Iswitch=Vref/Rref and I_{DC}=Vref/Rref*K, where Vref is a reference voltage, Rref is a reference resistance, 1/K is a duty ratio offset, a resistance of the sensing circuit is defined as R_{CS}, and the comparison output is defined as DI, then the current in the output inductor can be defined as
$$Iinductor = ( DI - \frac{1}{K} ) * ( \frac{Vref}{DCR} ) * ( \frac{Rcs}{Rref} )$$

13. The circuit of claim 1, having two or more switching power supplies.

14. The circuit of claim 13, wherein the switched current source circuit comprises at least two current sources defined as Iswitch=Vref/Rref and I_{DC}=Vref/Rref*K, where Vref is a reference voltage, Rref is a reference resistance, 1/K is a duty ratio offset, a resistance of the sensing circuit is defined as R_{CS}, and the comparison output is defined as
$$( \frac{Iinductor 1 * D C R 1}{Rcs 1} + \frac{Iinductor 2 * DCR 2}{Rcs 2} ) * ( Rref ) * ( \frac{1}{Vref} ) + \frac{1}{K}$$

15. The circuit of claim 1, further comprising a conversion circuit for converting the pulse width modulated signal to an analog voltage output proportional to the inductor current, the conversion circuit including a switching stage having high- and low-side switches connected at a node.

16. The circuit of claim 15 wherein the analog voltage output is defined as VavgDI=average(Iinductor)*Vmult*scalar, where Vmult is a voltage powering the switching stage.

17. The circuit of claim 15 wherein the analog voltage output is defined as VavgDI=average(Iinductor)*Vout*scalar where Vout is the output voltage of the switching power supply powering the switching stage.

18. The circuit of claim 12, further comprising a first resistor for sensing the current in the output inductor and wherein the analog voltage output is defined as
$$Iinductor = ( DI - \frac{1}{K} ) * ( \frac{Vref}{Rsense} ) * ( \frac{Rcs}{Rref} ) .$$

19. The circuit of claim 18, further comprising a circuit to convert the comparison output to average current over a time interval, wherein when inductor current is zero there is equal number of ones and zeros, for negative inductor currents there are fewer ones than zeros and for positive inductor currents there are more ones than zeros.

20. The circuit of claim 1, wherein the sensing circuit utilizes the direct current resistance (DCR) of the inductor to determine the inductor current.

21. The circuit of claim 1, wherein the sensing circuit uses a separate resistance in series with the output inductor to determine inductor current.

22. The circuit of claim 20, wherein the sensing circuit comprises first and second filter circuits, the first filter circuit comprising a first RC circuit disposed across said output inductor and said second filter circuit comprising a second RC circuit disposed across a capacitor of said first RC circuit, the time constant of the first filter circuit is made equal the time constant of the DCR and inductance of the inductor.

23. The circuit of claim 22, wherein said second RC circuit has a negative temperature coefficient to counteract a positive temperature coefficient of said first RC circuit.
